(19) United States
(12) Patent Application Publication
(10) Pub. No.: US 2026/0157094 A1
(43) Pub. Date: Jun. 4, 2026

(54) DISPLAY DEVICE AND ELECTRONIC DEVICE INCLUDING THE SAME

(71) Applicant: Samsung Display Co., Ltd., Yongin-Si (KR)

(72) Inventors: JAEIK LIM, Yongin-si (KR); IN-BAE KIM, Yongin-si (KR); BEOMSOO PARK, Yongin-si (KR); Eunji LIM, Yongin-si (KR)

(21) Appl. No.: 19/379,877

(22) Filed: Nov. 5, 2025

(30) Foreign Application Priority Data
Dec. 3, 2024 (KR) 10-2024-0177306

(51) Int. Cl. H10K 59/80; H10K 59/122; H10K 59/40

(52) U.S. Cl. CPC H10K 59/8791; H10K 59/122; H10K 59/40

(57) ABSTRACT

Provided is a display device which includes a display panel including a light-emitting element, an input sensor disposed on the display panel, and an anti-reflection layer disposed on the input sensor. The input sensor includes a sensor conductive layer including a plurality of first conductive patterns, a sensor organic layer covering the plurality of first conductive patterns, and a sensor inorganic layer disposed on the sensor organic layer and in contact with an upper surface of the sensor organic layer. An opening is defined in the sensor inorganic layer.

### CROSS-REFERENCE TO RELATED APPLICATIONS

This U.S. non-provisional patent application claims priority, under 35 U.S.C. § 119, to Korean Patent Application No. 10-2024-0177306 filed on Dec. 3, 2024, the contents of which are hereby incorporated by reference.

### BACKGROUND

The present disclosure herein relates to a display device and an electronic device including the same, and more particularly, to a display device and an electronic device including an input sensor.

Multimedia devices such as a television, a mobile phone, a tablet computer, a navigation unit, and a game console include display devices which display images to a user through a display screen. The display devices include a keyboard or a mouse as an input device thereof. Additionally, the display devices are provided with an input sensor as the input device.

The input sensor may include a conductor that detects an external input, and the conductor of the input sensor disposed on the display panel may affect an impact resistance or a light emission efficiency of a display device.

### SUMMARY

The present disclosure provides a display device with an improved impact resistance and light emission efficiency, and an electronic device including the same.

An embodiment of the inventive concept provides a display device including: a display panel including a light-emitting element that includes at least one first electrode, at least one light-emitting layer disposed on the at least one first electrode, and a second electrode disposed on the light-emitting layer; an input sensor disposed on the display panel; and an anti-reflection layer disposed on the input sensor, wherein the input sensor includes a sensor conductive layer including a plurality of first conductive patterns, a sensor organic layer configured to cover the plurality of first conductive patterns, and a sensor inorganic layer disposed on the sensor organic layer and in contact with an upper surface of the sensor organic layer, and an opening is defined in the sensor inorganic layer.

In an embodiment, the display panel may further include a pixel defining layer, the light-emitting element may include a first light-emitting element configured to generate first-color light, a first light-emitting opening defined in the pixel defining layer and exposing one of the at least one the first electrode, wherein the opening may include a first opening overlapping the first light-emitting opening.

In an embodiment, wherein a first cavity connected to the first opening may be defined in the sensor organic layer, the sensor organic layer may include a floor surface and a side surface extending from the floor surface to form an acute angle, the floor surface and the side surface defining the first cavity, and a central region of the one of the at least one first electrode may overlap the floor surface of the first cavity.

In an embodiment, the anti-reflection layer may include a first color filter disposed in the first cavity to overlap the first light-emitting element, and a refractive index of the first color filter may be greater than a refractive index of the sensor organic layer.

In an embodiment, the light-emitting element may further include a second light-emitting element configured to generate second-color light different from the first-color light, a second light-emitting opening may be defined in the pixel defining layer and exposes another one of the at least one first electrode, and the opening may further include a second opening not overlapping the second light-emitting opening, and overlapping the pixel defining layer.

In an embodiment, the anti-reflection layer may include a second color filter disposed to overlap the second light-emitting element, a refractive index of the second color filter may be smaller than a refractive index of the sensor organic layer, and the second opening may have a ring shape on a plane.

In an embodiment, a second cavity connected to the second opening may be further defined in the sensor organic layer, and the second color filter may be disposed in the second cavity.

In an embodiment, on a plane, the sensor inorganic layer may include a first portion surrounded by the second opening, and a second portion disposed outside the second opening.

In an embodiment, the light-emitting element may further include a third light-emitting element configured to generate third-color light different from the first-color light, and the anti-reflection layer, in which a color opening overlapping the first light-emitting element is defined, may include a third color filter overlapping the pixel define layer and the third light-emitting element.

In an embodiment, the display panel further may include a pixel defining layer, the anti-reflection layer may include a light-blocking pattern overlapping the pixel defining layer, and a color filter configured to cover the opening and the light-blocking pattern, and the light-blocking pattern may include a black coloring agent that absorbs light.

In an embodiment, the display panel may further include a pixel define layer, a light-emitting opening may be defined in the pixel defining layer and expose the at least one first electrode, a cavity connected to the opening may be defined in the sensor organic layer, the sensor organic layer may include a floor surface and a side surface extending from the floor surface to form an acute angle and define the cavity, and on a plane, a distance between an edge of the light-emitting opening and an edge of the floor surface may be about 2.5 μm or less.

In an embodiment, a cavity connected to the opening may be defined in the sensor organic layer, the sensor organic layer may include a floor surface and a side surface extending from the floor surface to form an acute angle and define the cavity, and the cavity, measured from a center of the floor surface, may have a depth of about 0.5 μm to about 3.0 μm.

In an embodiment of the inventive concept, a display device incudes: a display panel including a light-emitting element; and an input sensor disposed on the display panel, wherein the display panel includes a pixel defining layer, the light-emitting element includes a first electrode, a light-emitting layer disposed on the first electrode, and a second electrode disposed on the light-emitting layer, a light-emitting opening defined in the pixel defining layer and exposing the first electrode, the input sensor includes a sensor conductive layer including a plurality of first conductive pattern, a sensor organic layer configured to cover the plurality of first conductive patterns, and an impact buffer layer disposed on the sensor organic layer and having a greater elastic modulus than the sensor organic layer, an opening is defined in the impact buffer layer, and a cavity is defined in the sensor organic layer and connected to the opening.

In an embodiment, the impact buffer layer may include a material having an elastic modulus of about 10 GPa to about 150 GPa.

In an embodiment, an anti-reflection layer may be disposed on the input sensor, the anti-reflection layer may include a color filter overlapping the light-emitting opening, the light-emitting element may include a first light-emitting element configured to emit first-color light, and a second light-emitting element configured to emit the second-color light different from the first-color light, the color filter may include a first color filter disposed to overlap the first light-emitting element, and a second color filter disposed to overlap the second light-emitting element, a refractive index of the sensor organic layer may be smaller than a refractive index of the first color filter and may be greater than a refractive index of the second color filter, and the opening may include a first opening overlapping the light-emitting opening and a second opening overlapping the pixel define layer.

In an embodiment, the cavity may include a first cavity extending from the first opening, and a second cavity extending from the second opening.

In an embodiment, on a plane, an area of the first opening may be greater than an area of the second opening.

In an embodiment of the inventive concept, an electronic device includes: a display device; an electronic module; and a housing coupled to the display device, wherein the display device includes a display panel including a light-emitting element; an input sensor disposed on the display panel; and an anti-reflection layer disposed on the input sensor, and the input sensor includes a sensor conductive layer including a plurality of first conductive patterns a sensor organic layer configured to cover the plurality of first conductive patterns, and a sensor inorganic layer disposed on the sensor organic layer and in contact with an upper surface of the sensor organic layer, and an opening is defined in the sensor inorganic layer.

In an embodiment, the display panel may further include a pixel defining layer, the light-emitting element may include a first electrode, a light-emitting layer disposed on the first electrode, and a second electrode disposed on the light-emitting layer, a light-emitting opening may be defined in the pixel defining layer and expose the first electrode, the opening may include a first opening overlapping the light-emitting opening and a second opening overlapping the pixel define layer, and a first cavity extending from the first opening and a second cavity extending from the second opening may be defined in the sensor organic layer.

In an embodiment, the display device may not include a polarizing plate.

### BRIEF DESCRIPTION OF THE FIGURES

The accompanying drawings are included to provide an understanding of the inventive concept, and are incorporated in and constitute a part of this specification. The drawings illustrate embodiments of the inventive concept and, together with the description, serve to explain principles of the inventive concept. In the drawings:

FIGS. 1A to 1C are perspective views of an electronic device according to an embodiment of the inventive concept;

FIG. 2A is an exploded perspective view of an electronic device according to an embodiment of the inventive concept;

FIG. 2B is a block diagram of an electronic device according to an embodiment of the inventive concept;

FIG. 3 is a plan view of a display panel according to an embodiment of the inventive concept;

FIG. 4 is an enlarged plan view of a portion of a display region of a display panel according to an embodiment of the inventive concept;

FIG. 5 is a cross-sectional view of a display module according to an embodiment of the inventive concept;

FIG. 6 is an enlarged cross-sectional view of a portion of a display module according to an embodiment of the inventive concept;

FIGS. 7A and 7B are respectively cross-sectional views of a display module according to an embodiment of the present invention;

FIGS. 8A to 8D are respectively enlarged plan views of a portion of a sensor inorganic layer according to an embodiment of the inventive concept;

FIGS. 9A and 9B are respectively enlarged cross-sectional views of a portion of a display module according to an embodiment of the inventive concept; and

FIGS. 10A and 10B are respectively enlarged plan views of a portion of a sensor inorganic layer according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

In this specification, it will be understood that “being directly disposed” means that there are no intervening layer, film, region, plate, or the like between a portion of a layer, film, region, plate, or the like and another portion thereof. For example, “being directly disposed” may mean to be disposed between two layers or two members without using an additional member such as an adhesive member or like.

Like reference numerals or symbols refer to like elements throughout. In the drawings, the thickness, ratio, and size of the elements are exaggerated for effectively describing the technical contents. The term “and/or” includes all of one or more combinations defined by the associated elements.

Although the terms first, second, etc., may be used to describe various elements, these elements should not be limited by these terms. These terms are only used to distinguish one element, component, region, layer or section from another element, component, region, layer or section. For instance, a first element could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the drawings.

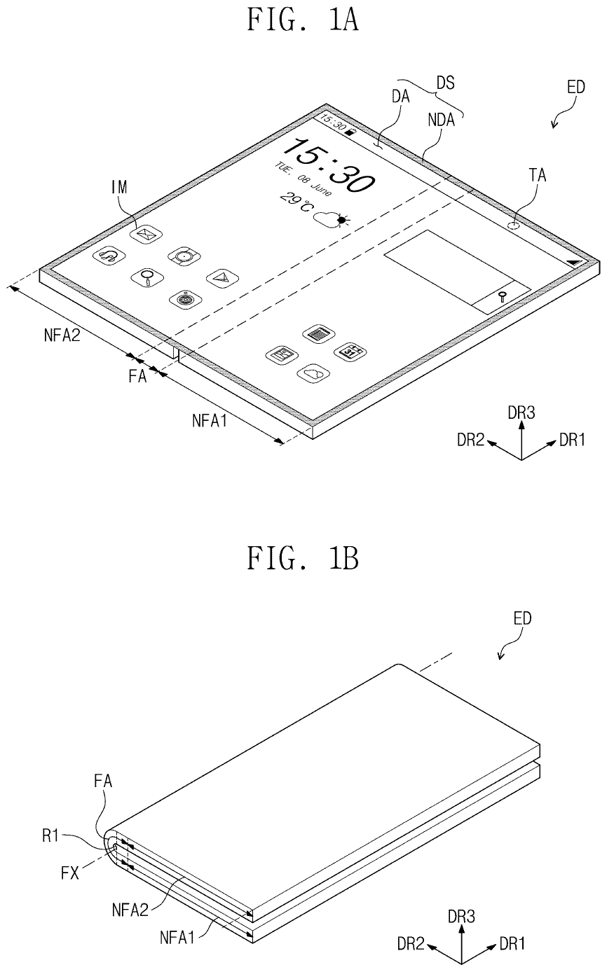

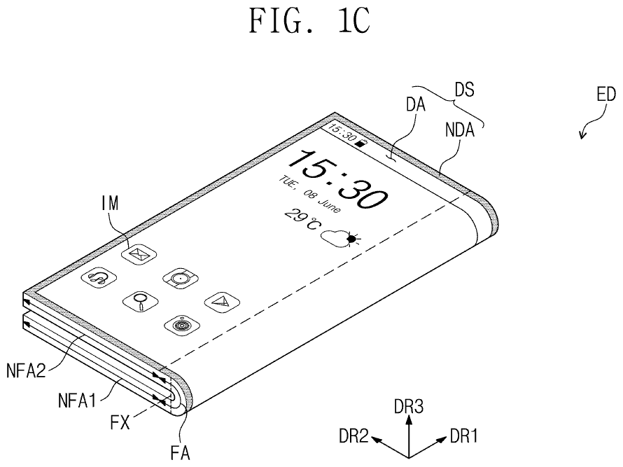

FIGS. 1A to 1C are perspective views of an electronic device ED according to an embodiment of the inventive concept. FIG. 1A illustrates an unfolded state of the electronic device ED, and FIGS. 1B and 1C respectively illustrate two different folded states of the electronic device ED.

Referring to FIGS. 1A to 1C, the electronic device ED according to an embodiment of the inventive concept may include a display surface DS defined by a first direction DR1 and a second direction DR2 crossing the first direction DR1. The electronic device ED may provide an image IM to a user through the display surface DS.

The display surface DS may include a display region DA and a non-display region NDA around the display region DA. The display region DA may display the image IM, and the non-display region NDA may not display the image IM. The non-display region NDA may surround the display region DA. However, the embodiment of the inventive concept is not limited thereto, and a shape of the display region DA and a shape of the non-display region NDA may be changed.

The display surface DS may include a sensing region TA. The sensing region TA may be a partial region of the display region DA. The sensing region TA has higher transmittance than other regions of the display region DA. Hereinafter, the regions of the display region DA other than the sensing region TA may be defined as a general display region.

An optical signal, for example, visible light or infrared light, may transmit to the sensing region TA. The electronic device ED may capture an external image using the visible light passing through the sensing region TA or determine whether an external object is approaching by using the infrared light. FIG. 1A illustrates one sensing region TA, but an embodiment of the inventive concept is not limited thereto. A plurality of sensing regions TA may be provided.

Hereinafter, a direction which is substantially perpendicular to a plane defined by the first direction DR1 and the second direction DR2 is defined as a third direction DR3. The third direction DR3 is a reference direction which distinguishes a front surface and a rear surface of each of components. In this specification, the wording “on a plane” may be defined as a state when viewed in the third direction DR3. Hereinafter, the first to third directions DR1, DR2, and DR3 are the directions indicated by respective first to third directional axes, and are denoted using the same reference numerals or symbols.

The electronic device ED may include a folding region FA and a plurality of non-folding regions NFA1 and NFA2. The non-folding regions NFA1 and NFA2 may include a first non-folding region NFA1 and a second non-folding region NFA2. In the second direction DR2, the folding region FA may be disposed between the first non-folding region NFA1 and the second non-folding region NFA2.

As illustrated in FIG. 1B, the folding region FA of the electronic device ED may be folded with respect to a folding axis FX parallel to the first direction DR1. The folding region FA has a predetermined curvature and a curvature radius R1. The electronic device ED may be inward-folded (in-folded) such that the first non-folding region NFA1 and the second non-folding region NFA2 face each other and the display surface DS is not exposed.

As illustrated in FIG. 1C, the electronic device ED may be outward-folded (out-folded) such that the display surface DS is exposed. In an embodiment of the inventive concept, the electronic device ED may be configured to repeatedly perform an in-folding or out-folding operation from an unfolded state and vice versa, but an embodiment of the inventive concept is not limited thereto. In an embodiment of the inventive concept, the electronic device ED may be configured to perform any one of the unfolding operation, the in-folding operation, and the out-folding operation.

A foldable electronic device ED is illustrated in the embodiment of the inventive concept, but the embodiment of the inventive concept is not limited thereto. The electronic device ED may be a flat electronic device or may also be a rollable electronic device. In an embodiment of the inventive concept, the electronic device ED is exemplarily illustrated as a mobile phone, but is not limited thereto. In an embodiment of the inventive concept, the electronic device ED may be applied to large-sized electronic devices such as a television and a monitor, as well as to a small- and medium-sized electronic devices such as a tablet computer, a car navigation system, a game console, and a smart watch.

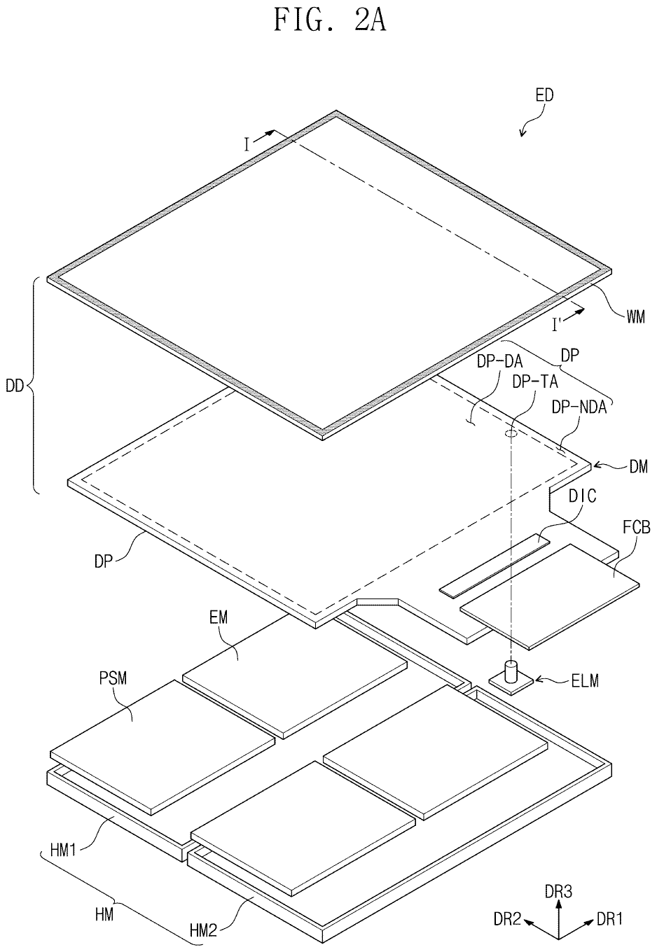

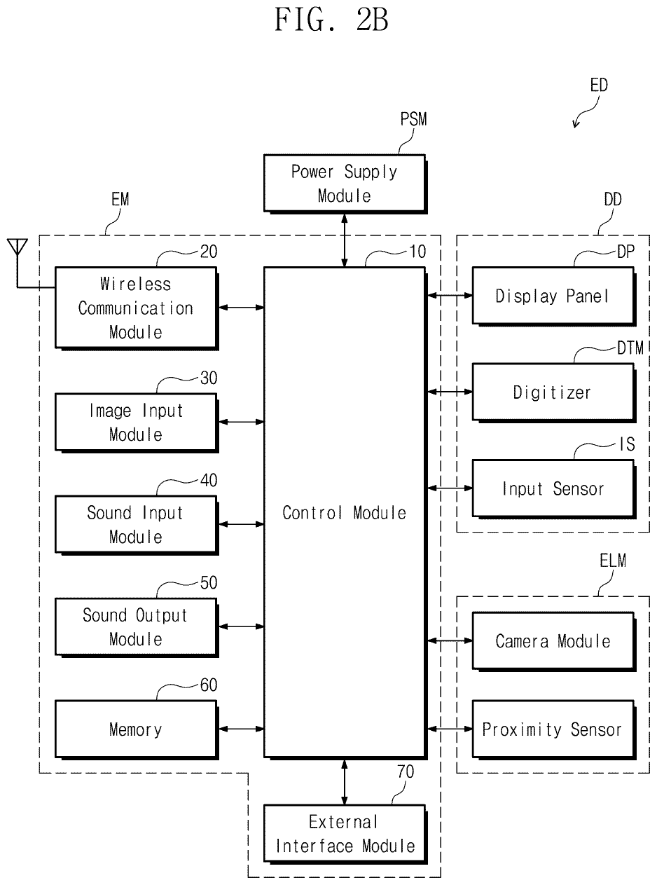

FIG. 2A is an exploded perspective view of an electronic device ED according to an embodiment of the inventive concept. FIG. 2B is a block diagram of the electronic device ED according to an embodiment of the inventive concept.

As illustrated in FIG. 2A, the electronic device ED may include a display device DD, an electronic module EM, an electronic optical module ELM, a power supply module PSM, and a housing HM. Although not illustrated separately, the electronic device ED may further include mechanical structures for controlling a folding operation of the display device DD.

The display device DD generates an image and detects an external input. The display device DD includes a window WM and a display module DM. The window WM provides a front surface of the electronic device ED. The window WM will be described later in detail.

The display module DM may include at least a display panel DP. FIG. 2A illustrates only the display panel DP among stacked structures of the display module DM, but substantially, the display module DM may further include a plurality of components disposed above the display panel DP. The stack structure of the display module DM will be described later in detail.

The display panel DP may be a light-emitting display panel, but is not particularly limited. For example, the display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots and/or quantum rods, etc. Hereinafter, the display panel DP is described as the organic light-emitting display panel.

The display panel DP includes a display region DP-DA and a non-display region DP-NDA respectively corresponding to the display region DA (see FIG. 1A) and the non-display region NDA (see FIG. 1A) of the electronic device ED. In this specification, the wording “a region/portion corresponds to a region/portion” means “overlapping each other”, and the region/portion is not limited to having the same area.

The display panel DP may include a sensing region DP-TA corresponding to the sensing region TA of FIG. 1A. The sensing region DP-TA may be a region having lower resolution than the display region DP-DA. The sensing region DP-TA will be described later in detail.

As illustrated in FIG. 2A, a driver chip DIC may be disposed on the non-display region DP-NDA of the display panel DP. A flexible circuit board FCB may be coupled to the non-display region DP-NDA of the display panel DP. The flexible circuit board FCB may be connected to a main circuit board. The main circuit board may be one electronic component which constitutes the electronic module EM.

A driver chip DIC may include driving elements for driving pixels of the display panel DP, for example, a data driving circuit. FIG. 2A illustrates a structure in which the driver chip DIC is mounted on the display panel DP, but an embodiment of the inventive concept is not limited thereto. For example, the driver chip DIC may also be mounted on the flexible circuit board FCB.

As illustrated in FIG. 2B, the display device DD may further include an input sensor IS and a digitizer DTM. The input sensor IS detects a user's input. A capacitive input sensor IS may be disposed on the display panel DP. The digitizer DTM detects a stylus pen's input. An electromagnetic digitizer DTM may be disposed below the display panel DP.

The electronic module EM may include a control module 10, a wireless communication module 20, an image input module 30, a sound input module 40, a sound output module 50, a memory 60, an external interface module 70, etc. The electronic module EM may include a main circuit board, and the modules may be mounted on the main circuit board or be electrically connected to the main circuit board via a flexible circuit board. The electronic module EM is electrically connected to a power supply module PSM.

Referring to FIGS. 2A and 2B, the electronic module EM may be disposed in each of a first housing HM1 and a second housing HM2, and a power supply module PSM may be disposed in each of the first housing HM1 and the second housing HM2. Although not illustrated, the electronic module EM disposed in the first housing HM1 may be electrically connected to the electronic module EM disposed in the second housing HM2 via the flexible circuit board.

The control module 10 controls overall operations of the electronic device ED. For example, the control module 10 activates or deactivates the display device DD in response to a user's input. The control module 10 may control the image input module 30, the sound input module 40, the sound output module 50, etc., in response to the user's input. The control module 10 may include at least one microprocessor.

The wireless communication module 20 may transmit/receive wireless signals to/from another terminal through a Bluetooth or Wi-Fi line. The wireless communication module 20 may transmit/receive voice signals through a typical communication line. The wireless communication module 20 may include a plurality of antenna modules.

The image input module 30 processes an image signal and converts the image signal into displayable image data on the display device DD. The sound input module 40 receives an external sound signal by using a microphone in a recording mode, a voice recognition mode, etc., and converts the received sound signal into electrical voice data. The sound output module 50 converts sound data received from the wireless communication module 20 or sound data stored in the memory 60, and outputs the converted sound data to the outside.

The external interface module 70 serves as an interface connected to an external charger, wired/wireless data ports, a card socket (for example, a memory card, a SIM/UIM card), etc.

The power supply module PSM supplies power required for the overall operation of the electronic device ED. The power supply module PSM may include a typical battery device.

The electronic optical module ELM may be an electronic component which outputs or receives an optical signal. The electronic optical module ELM may include a camera module and/or a proximity sensor. The camera module captures an external image via the sensing region DP-TA.

The housing HM illustrated in FIG. 2A is coupled to the display device DD, particularly, to the window WM, and accommodates other modules described above.

It is illustrated that the housing HM includes the first and second housings HM1 and HM2 separated from each other, but an embodiment of the inventive concept is not limited thereto. Although not illustrated, the electronic device ED may further include a hinge structure for connecting the first and second housings HM1 and HM2.

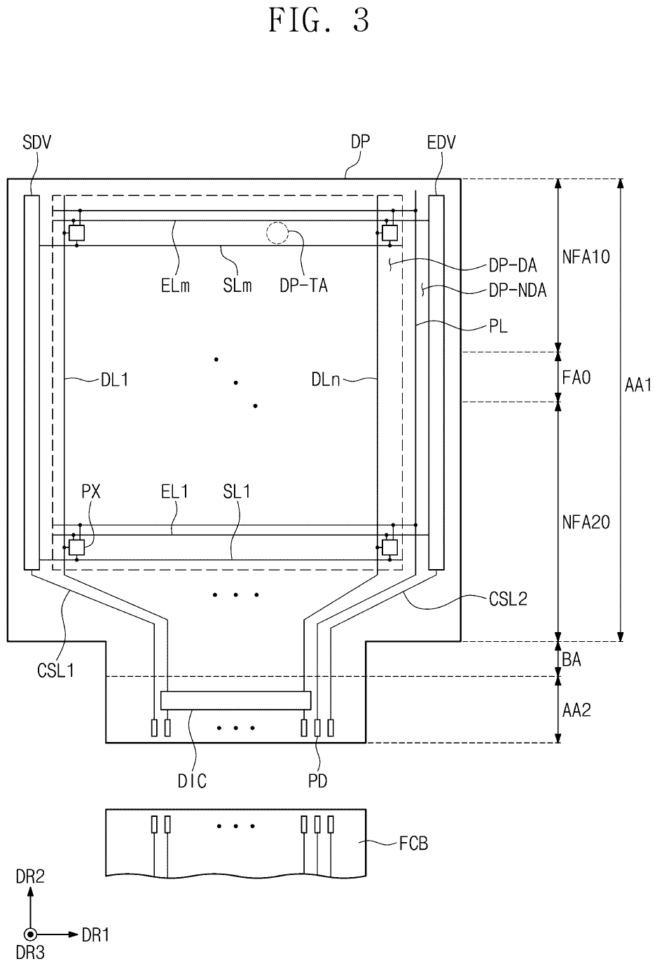

FIG. 3 is a plan view of a display panel DP according to an embodiment of the inventive concept.

Referring to FIG. 3, the display panel DP may include a display region DP-DA and a non-display region DP-NDA around the display region DP-DA. The display region DP-DA and the non-display region DP-NDA are distinguished by a pixel PX. The pixel PX is disposed in the display region DP-DA. A scan driver SDV, a data driver, and an emission driver EDV may be disposed in the non-display region DP-NDA. The data driver may be a portion of circuits constituted in the driver chip DIC.

The display panel DP includes a first region AA1, a second region AA2, and a bending region BA which are separated in the second direction DR2. The second region AA2 and the bending region BA may be a partial region of the non-display region DP-NDA. The bending region BA is disposed between the first region AA1 and the second region AA2.

The first region AA1 is a region which corresponds to the display surface DS of FIG. 1A. The first region AA1 may include a first non-folding region NFA10, a second non-folding region NFA20, and a folding region FAO. The first non-folding region NFA10, the second non-folding region NFA20, and the folding region FAO respectively correspond to the first non-folding region NFA1, the second non-folding region NFA2, and the folding region FA of FIGS. 1A to 1C.

The lengths of the bending region BA and the second region AA2 may be smaller than the length of the first region AA1 in the first direction DR1. A region having a shorter length in a bending axis direction may be bent more easily.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power supply line PL, and a plurality of pads PD. Here, m and n are natural numbers. The pixels PX may be connected to the scan lines SL1 to SLm, the data lines DL1 to DLn, and the emission lines EL1 to ELm.

The scan lines SL1 to SLm may extend in the first direction DR1 to be connected to the scan driver SDV. The data lines DL1 to DLn may extend in the second direction DR2 to be connected to the driver chip DIC via the bending region BA. The emission lines EL1 to ELm may extend in the first direction DR1 to be connected to an emission driver EDV.

The power supply line PL may include a portion extending in the second direction DR2 and a portion extending in the first direction DR1. The portion extending in the first direction DR1 and the portion extending in the second direction DR2 may be disposed on different layers. A portion of the power supply line PL extending in the second direction DR2 may extend to the second region AA2 via the bending region BA. The power supply line PL may provide a first voltage to the pixels PX.

The first control line CSL1 may be connected to the scan driver SDV and extend toward a lower end of the second region AA2 via the bending region BA. The second control line CSL2 may be connected to the emission driver EDV and extend toward the lower end of the second region AA2 via the bending region BA.

On a plane, pads PD may be disposed adjacent to the lower end of the second region AA2. The driver chip DIC, the power supply line PL, the first control line CSL1, and the second control line CSL2 may be connected to the pads PD. The flexible circuit board FCB may be electrically connected to the pads PD via an anisotropic conductive adhesive layer.

The sensing region DP-TA may be a region having a higher light transmittance and lower resolution than the display region DP-DA. The light transmittance and resolution are measured within a reference area. The sensing region DP-TA has an occupancy ratio of a light-blocking structure smaller than that of the display region DP-DA within the reference area. The light-blocking structure may include conductive patterns of a circuit layer, electrodes of a light-emitting element, light-blocking patterns, etc., which are described later.

The sensing region DP-TA has a smaller number of pixels than that of the display region DP-DA within the reference area (or the same area). Substantially, the sensing region DP-TA may be a region through which an optical signal passes.

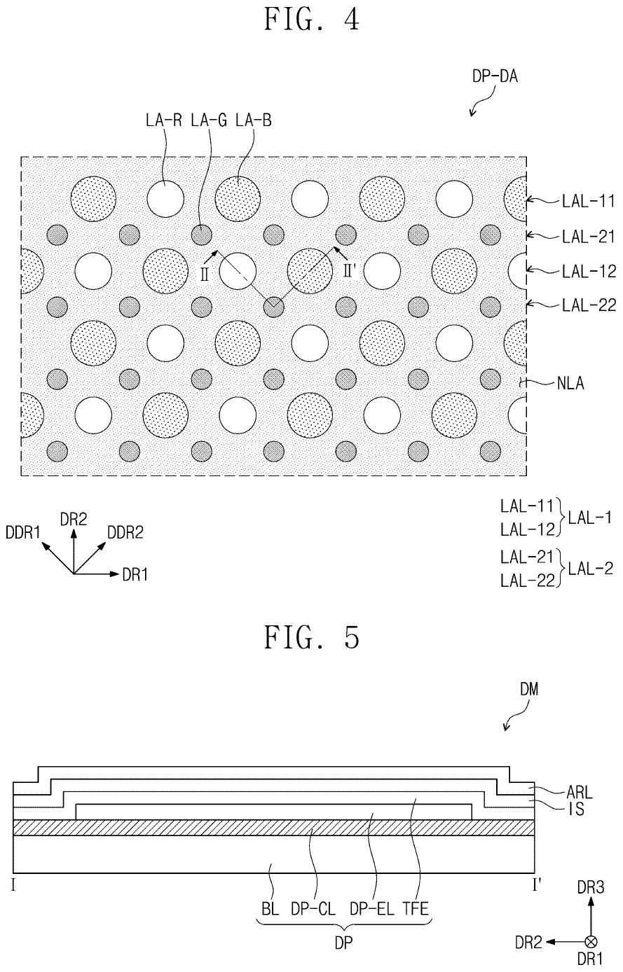

FIG. 4 is an enlarged plan view illustrating a portion of a display region DP-DA of a display panel DP according to an embodiment of the inventive concept.

Referring to FIG. 4, a plurality of light-emitting regions LA-R, LA-G, and LA-B are disposed in the display region DP-DA. A non-light-emitting region NLA is disposed adjacent to the plurality of light-emitting regions LA-R, LA-G, and LA-B. The non-light-emitting regions NLA define the boundaries of the plurality of light-emitting regions LA-R, LA-G, and LA-B, and prevent color-mixing between the plurality of light-emitting regions LA-R, LA-G, and LA-B. The plurality of light-emitting regions LA-R, LA-G, and LA-B may define a plurality of light-emitting rows LAL-1 and LAL-2 extending in the first direction DR1. In FIG. 4, the first direction DR1 is defined as an extending direction (or a row direction) of the light-emitting rows LAL-1 and LAL-2, and the second direction DR2 is defined as a column direction.

In an embodiment of the inventive concept, the plurality of light-emitting rows LAL-1 and LAL-2 may be separated as two groups. The light-emitting rows LAL-1 of a first group include a first color light-emitting region LA-R which generates first-color light, and a third color light-emitting region LA-B which generates third-color light. The first color light-emitting regions LA-R are alternately disposed with the third color light-emitting regions LA-B along the row direction DR1. The light-emitting rows LAL-1 of the first group may include a first light-emitting row LAL-11 and a second light-emitting row LAL-12. The first light-emitting rows LAL-11 and the second light-emitting rows LAL-12 may be alternately disposed along the column direction DR2.

The first light-emitting row LAL-11 and the second light-emitting row LAL-12 both have the first color light-emitting regions LA-R and the third color light-emitting regions LA-B but they are offset by one region with respect to each other in the first direction DR1. With this offset, in the column direction DR2, the first color light-emitting region LA-R and the third color light-emitting region LA-B alternate. For example, the first color light-emitting region LA-R of the first light-emitting row LAL-11 and the third color light-emitting region LA-B of the second light-emitting row LAL-12 are aligned in the second direction DR2, and the third color light-emitting region LA-B of the first light-emitting row LAL-11 and the first color light-emitting region LA-R of the second light-emitting row LAL-12 may be aligned in the second direction DR2.

The light-emitting rows LAL-2 of a second group may include a second color light-emitting region LA-G which generates second-color light. The light-emitting rows LAL-2 of the second group may include a third light-emitting row LAL-21 and a fourth light-emitting row LAL-22.

The third light-emitting row LAL-21 and the fourth light-emitting row LAL-22 may include the second color light-emitting region LA-G extending in the first direction DR1. The third light-emitting rows LAL-21 and the fourth light-emitting rows LAL-22 may be alternately disposed along the column direction DR2.

In an embodiment of the inventive concept, the first color light-emitting region LA-R, the second-color light-emitting region LA-G, and the third-color light-emitting region LA-B are exemplarily illustrated to have different planar areas, but an embodiment of the inventive concept is not limited thereto. It is illustrated that among the above light-emitting regions, the third color light-emitting region LA-B has the largest area, and the second color light-emitting region LA-G has the smallest area, but this is merely illustrated as an example.

In an embodiment of the inventive concept, the first color light-emitting region LA-R may generate red light, the second color light-emitting region LA-G may generate green light, and the third color light-emitting region LA-B may generate blue light. However, an embodiment of the inventive concept is not limited thereto, and the color light emitted by the first color light-emitting region LA-R, the second color light-emitting region LA-G, and the third color light-emitting region LA-B may be selected from a combination of three colors of light that are capable of generating white light upon mixing.

In an embodiment of the inventive concept, the plurality of light-emitting regions LA-R, LA-G, and LA-B having a circular shape are illustrated, but shapes are not limited thereto, and also may have a polygonal shape.

FIG. 5 is a cross-sectional view of a display module DM according to an embodiment of the inventive concept. FIG. 5 illustrates a cross section of the display module DM taken along line I-I′ of FIG. 2A.

Referring to FIG. 5, the display module DM may include a display panel DP, an input sensor IS, and an anti-reflection layer ARL. The display panel DP may include a base layer BL, a circuit layer DP-CL, a light-emitting element layer DP-EL, and an encapsulation layer TFE.

The base layer BL may provide a base surface on which the circuit layer DP-CL is disposed. The base layer BL may be a flexible substrate which is bendable, foldable, rollable, etc. The base layer BL may be a glass substrate, a metal substrate, a polymer substrate, or the like. However, an embodiment of the inventive concept is not limited thereto, and the base layer BL may be an inorganic layer, an organic layer, or a composite material layer.

The base layer BL may have a multi-layered structure. For example, the base layer BL may include a first synthetic resin layer, a multi- or single-layered inorganic layer, or a second synthetic resin layer disposed on the multi- or single-layered inorganic layer. The first and second synthetic resin layers may each include a polyimide-based resin, and are not particularly limited.

The circuit layer DP-CL may be disposed on the base layer BL. The circuit layer DP-CL may include an insulating layer, a semiconductor pattern, a conductive pattern, a signal line, etc.

The light-emitting element layer DP-EL may be disposed on the circuit layer DP-CL. The light-emitting element layer DP-EL may include a light-emitting element. For example, a light-emitting element may include an organic light-emitting material, an inorganic light-emitting material, an organic-inorganic light-emitting material, quantum dots, quantum rods, a micro LED, or a nano LED.

The encapsulation layer TFE may be disposed on the light-emitting element layer DP-EL. The encapsulation layer TFE may protect the light-emitting element layer DP-EL against moisture, oxygen, and foreign substances such as dust particles. The encapsulation layer TFE may include at least one inorganic layer. The encapsulation layer TFE may include a stacked structure of an inorganic layer/an organic layer/an inorganic layer.

The input sensor IS may be directly disposed on the display panel DP. The input sensor IS may be formed on the display panel DP through a continuous process. Here, the wording, “being directly disposed” may mean that another component is not disposed between the input sensor IS and the display panel DP. That is, a separate adhesive member may not be disposed between the input sensor IS and the display panel DP. The display panel DP generates images, and the input sensor IS acquires coordinate information about an external input (for example, a touch event).

The anti-reflection layer ARL may be directly disposed on the input sensor IS. The anti-reflection layer ARL may reduce a reflectivity for external light (for example, natural light or solar light) incident on the display device DD from the outside. The anti-reflection layer ARL may include color filters. The color filters may have a predetermined arrangement. For example, the color filters may be arranged in consideration of colors of light emitted from pixels which are included in the display panel DP. Additionally, the anti-reflection layer ARL may further include a light-blocking pattern adjacent to the color filters.

In an embodiment of the inventive concept, positions of the input sensor IS and the anti-reflection layer ARL may be exchanged.

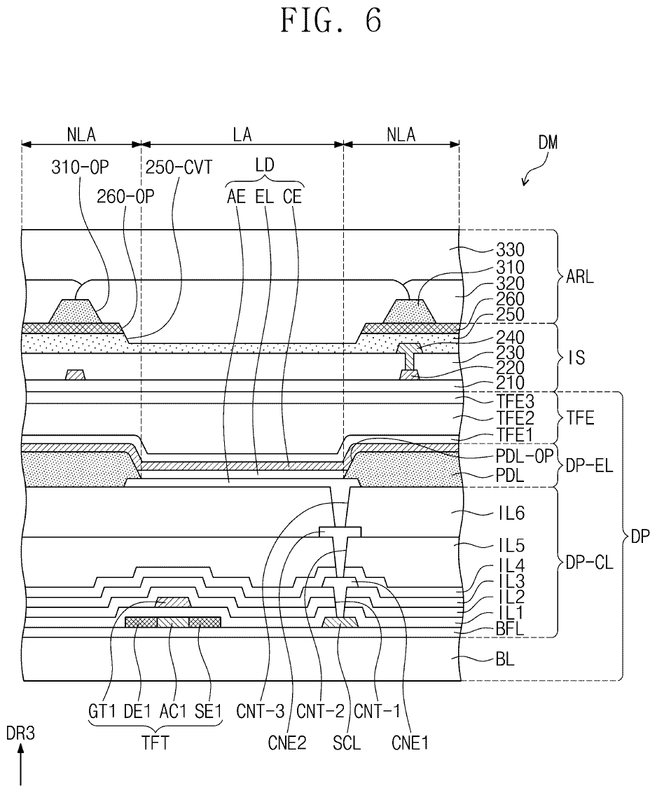

FIG. 6 is an enlarged cross-sectional view of a portion of a display module DM according to an embodiment of the inventive concept. FIG. 6 illustrates a portion of the display module DM, according to an embodiment, illustrated in FIG. 5. Referring to FIG. 6, the descriptions of configurations same as those described with reference to FIG. 5 will be omitted, and reference is made to the descriptions of FIG. 5.

FIG. 6 illustrates a cross-section corresponding to one light-emitting region LA and a non-light-emitting region NLA around the light-emitting region LA. FIG. 6 exemplarily illustrates only one light-emitting region LA, but the light-emitting region LA may be provided in plurality. FIG. 6 illustrates a light-emitting element LD and a transistor TFT connected to the light-emitting element LD. The transistor TFT may be one of a plurality of transistors included in a driving circuit of a pixel. In an embodiment of the inventive concept, the transistor TFT is described as a silicon transistor, but may also be a metal oxide transistor.

Referring to FIG. 6, the display module DM may include a display panel DP, an input sensor IS, and an anti-reflection layer ARL formed by performing a continuous process.

A buffer layer BFL may be disposed on a base layer BL. The buffer layer BFL may prevent metal atoms or impurities from diffusing from the base layer BL into a semiconductor pattern disposed on the buffer layer BFL. The semiconductor pattern includes an active region AC1. The buffer layer BFL may ensure uniform formation of the semiconductor pattern by controlling a heat supply rate during a crystallization process.

Although not illustrated, a rear metal layer may be disposed between the base layer BL and the buffer layer BFL. The rear metal layer may be disposed below the transistor TFT and block external light from reaching the transistor TFT.

The semiconductor pattern may be disposed on the buffer layer BFL. The semiconductor pattern may include a silicon semiconductor. For example, the silicon semiconductor may include amorphous silicon, polycrystalline silicon, etc. For example, the semiconductor pattern may include low-temperature polysilicon.

The semiconductor pattern may include a first region having high conductivity and a second region having low conductivity. The first region may be doped with an N-type dopant or a P-type dopant. A P-type transistor may include a doped region that is doped with the P-type dopant, and an N-type transistor may include a doped region which is doped with the N-type dopant. The second region may be a non-doped region or a region doped at a concentration lower than that of the first region.

The conductivity of the first region is greater than the conductivity of the second region, and the first region may substantially serve as an electrode or a signal line. The second region may substantially correspond to an active region (or a channel) of the transistor. That is, a portion of a semiconductor pattern may be an active region of a transistor, another portion may be a source or a drain of the transistor, and still another portion may be a connection electrode or a connection signal line.

The transistor TFT may include a source region SE1 (or a source), an active region AC1 (or a channel), a drain region DE1 (or a drain), and a gate region GT1 (or a gate). The source region SE1, the active region AC1, and the drain region DE1 of the transistor TFT may be formed from the semiconductor pattern. The source region SE1 and the drain region DE1 may extend from the active portion AC1 in directions opposite to each other on a cross section. FIG. 6 illustrates a portion of a signal transmission region SCL formed from the semiconductor pattern. Although not illustrated separately, the signal transmission region SCL may be connected to the drain DE1 of the transistor TFT on a plane.

A first insulating layer IL1 may be disposed on the buffer layer BFL and cover the semiconductor pattern. The first insulating layer IL1 may cover the source SE1, the active AC1, the drain DE1, and the signal transmission region SCL of the transistor TFT disposed on the buffer layer BFL.

The first insulating layer IL1 may be an inorganic layer and/or an organic layer and have a single- or multi-layered structure. The inorganic layer may include at least one of aluminum oxide, titanium oxide, silicon oxide, silicon nitride, silicon oxynitride, zirconium oxide, or hafnium oxide. In an embodiment of the inventive concept, the first insulating layer IL1 may be a single silicon oxide layer. Insulating layers of a circuit layer DP-CL, which will be described later, as well as the first insulating layer IL1 may be an inorganic layer and/or an organic layer, and may have a single- or multi-layered structure. The inorganic layer may include at least one of the above-described materials, but is not limited thereto.

The gate GT1 of the transistor TFT may be disposed on the first insulating layer IL1. The gate GT1 may be a portion of a metal pattern. The gate GT1 may overlap the active region AC1. During a process of doping the semiconductor pattern, the gate GT1 may function as a mask. The gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), etc., but the embodiment of the inventive concept is not particularly limited thereto.

A second insulating layer IL2 may be disposed on the first insulating layer IL1 and cover the gate GT1. A third insulating layer IL3 may be disposed on the second insulating layer IL2.

A first connection electrode CNE1 may be disposed on the third insulating layer IL3. The first connection electrode CNE1 may be connected to the signal transmission region SCL via a contact hole CNT-1 passing through the first to third insulating layers IL1, IL2, and IL3. A fourth insulating layer IL4 may be disposed on the third insulating layer IL3 and cover the first connection electrode CNE1. The fourth insulating layer IL4 may be an organic layer.

A fifth insulating layer IL5 may be disposed on the fourth insulating layer IL4. A second connection electrode CNE2 may be disposed on the fifth insulating layer IL5. The second connection electrode CNE2 may be connected to the first connection electrode CNE1 via a contact hole CNT-2 which passes through the fourth insulating layer IL4 and the fifth insulating layer IL5. The fifth insulating layer IL5 may be an organic layer.

A sixth insulating layer IL6 may be disposed on the fifth insulating layer IL5 and cover the second connection electrode CNE2. The sixth insulating layer IL6 may be an organic layer. A stacked structure of the first to sixth insulating layers IL1, IL2, IL3, IL4, IL5, and IL6 is merely presented as an example, and also, additional conductive layers and the insulating layers may be further disposed in addition to the first to sixth insulating layers IL1, IL2, IL3, IL4, IL5, and IL6.

A light-emitting element layer DP-EL may be disposed on the circuit layer DP-CL. The light-emitting element layer DP-EL may include a light-emitting element LD and a pixel defining layer PDL.

The light-emitting element LD may include a first electrode AE (or an anode), a light-emitting layer EL, and a second electrode CE (or a cathode). The second electrode CE may be disposed in a plurality of pixels PX in common.

The first electrode AE of the light-emitting element LD may be disposed on the sixth insulating layer IL6. The first electrode AE of the light-emitting element LD may be connected to the second connection electrode CNE2 via a contact hole CNT-3 which passes through the sixth insulating layer IL6. The first electrode AE of the light-emitting element LD may be a transflective electrode, or a reflective electrode. According to an embodiment of the inventive concept, the first electrodes AE of the light-emitting element LD may each include a reflective layer formed of Ag, Mg, Al, Pt, Pd, Au, Ni, Nd, Ir, Cr or a compound thereof, and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide (ZnO) or indium oxide (In2O3), and aluminum doped zinc oxide (AZO). For example, the first electrode AE of the light-emitting element LD may include a stacked structure of ITO/Ag/ITO.

The pixel defining layer PDL may be disposed on the sixth insulating layer IL6. The pixel defining layer PDL may absorb light and, for example, may have black color. The pixel defining layer PDL may include a black coloring agent. The black coloring agent may include a black dye and a black pigment. The black coloring agent may include carbon black, metal such as chromium, or oxides thereof. The pixel define layer PDL may correspond to a light-blocking pattern having light blocking characteristics.

The pixel defining layer PDL may cover a portion of the first electrode AE of the light-emitting element LD. For example, a light-emitting opening PDL-OP, which exposes a portion of the first electrode AE of the light-emitting element LD, may be defined in the pixel defining layer PDL. The light-emitting opening PDL-OP of the pixel defining layer PDL may define a light-emitting region LA. The pixel defining layer PDL may increase a distance between an edge of the first electrode AE and the second electrode CE. Thus, the pixel defining layer PDL may serve as preventing an arc, etc., from occurring at the edge of the first electrode AE.

Although not illustrated, a hole control layer may be disposed between the first electrode AE and the light-emitting layer EL. The hole control layer may include a hole transport layer, and further include a hole injection layer. An electron control layer may be disposed between the light-emitting layer EL and the second electrode CE. The electron control layer may include an electron transport layer and further include an electron injection layer.

An encapsulation layer TFE may be disposed on the light-emitting element layer DP-EL. The encapsulation layer TFE may include an inorganic layer TFE1, an organic layer TFE2, and an inorganic layer TFE3, which are sequentially stacked, but layers constituting the encapsulation layer TFE are not limited thereto.

The inorganic layers TFE1 and TFE3 may protect the light-emitting element layer DP-EL against moisture and oxygen, and the organic layer TFE2 may protect the light-emitting element layer DP-EL against foreign substances such as dust particles. The inorganic layers TFE1 and TFE3 may include a silicon nitride layer, a silicon oxynitride layer, a silicon oxide layer, a titanium oxide layer, an aluminum oxide layer, or the like. The organic layer TFE2 may include an acryl-based organic layer, but is not limited thereto.

The input sensor IS may be disposed on the display panel DP. The input sensor IS may be referred to as a sensor, an input-sensing layer, or an input-sensing panel. The input sensor IS may include a sensor insulation layer 210, a first sensor conductive layer 220, an intermediate sensor insulation layer 230, a second sensor conductive layer 240, a sensor organic layer 250, and a sensor inorganic layer 260. The sensor insulation layer 210 and the intermediate sensor insulation layer 230 may be omitted, and one of the first sensor conductive layer 220 or the second sensor conductive layer 240 may also be omitted.

The sensor insulation layer 210 may be directly disposed on the display layer DP. The sensor insulation layer 210 may be an inorganic layer which includes at least one of silicon nitride, silicon oxynitride, or silicon oxide. Alternatively, the sensor insulation layer 210 may also be an organic layer which includes an epoxy resin, an acrylic resin, or an imide-based resin. The sensor insulation layer 210 may have a single-layered structure or a multi-layered structure in which layers are stacked along the third direction DR3.

The first sensor conductive layer 220 and the second sensor conductive layer 240 may each have a single-layered structure or a multi-layered structure in which layers are stacked in the third direction DR3. The first sensor conductive layer 220 and the second sensor conductive layer 240 may include conductive patterns which define an electrode having a mesh shape. The conductive patterns may not overlap the light-emitting opening PDL-OP, and overlap the pixel defining layer PDL. In this specification, both the first sensor conductive layer 220 and the second sensor conductive layer 240 may be referred to as sensor conductive layers without being distinguished from each other.

The conductive layer having the single-layered structure may include a metal layer or a transparent conductive layer. The metal layer may include molybdenum, silver, titanium, copper, aluminum, or an alloy thereof. The transparent conductive layer may include transparent conductive oxides, such as indium tin oxide (ITO), indium zinc oxide (IZO), zinc oxide (ZnO), and indium zinc tin oxide (IZTO). In addition, the transparent conductive layer may include a conductive polymer, such as PEDOT, metal nanowire, graphene, and the like.

The conductive layer having the multi-layered structure may include metal layers which are sequentially stacked. The metal layers may also have, for example, a three-layered structure of titanium/aluminum/titanium. The conductive layer having the multi-layered structure may include at least one metal layer and at least one transparent conductive layer.

The intermediate sensor insulation layer 230 may be disposed between the first sensor conductive layer 220 and the second sensor conductive layer 240. The intermediate sensor insulation layer 230 may include an inorganic film. The inorganic film may include at least one of aluminum oxide, titanium oxide, silicon oxide, silicon nitride, silicon oxynitride, zirconium oxide, or hafnium oxide. Alternatively, the intermediate sensor insulation layer 230 may include an organic film. The organic film may include at least one of an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The sensor organic layer 250 is disposed on the second sensor conductive layer 240. Since the sensor organic layer 250 includes an organic material and is provided to have a predetermined thickness or more, an upper part of the conductive patterns of the conductive layer disposed below the sensor organic layer 250 may be planarized.

The sensor inorganic layer 260 may be disposed on the sensor organic layer 250. The sensor inorganic layer 260 may be directly disposed on the sensor organic layer 250. The sensor inorganic layer 260 may include an inorganic material, protect the conductive patterns disposed therebelow against external impact, and block moisture and oxygen.

According to an embodiment of the inventive concept, the sensor inorganic layer 260 may be referred to as an impact buffer layer, and the impact buffer layer 260 may have a larger elastic modulus than the sensor organic layer 250. The impact buffer layer 260 may include a material having a modulus of about 10 GPa to about 150 GPa. For example, the impact buffer layer 260 may include transparent conductive oxide (TCO) and metal. Accordingly, the impact buffer layer 260 may prevent the sensor organic layer 250 from being damaged by external impact, and thus the impact resistance may be improved.

An opening 260-OP overlapping the light-emitting region LA is defined in the sensor inorganic layer 260. A cavity 250-CVT extending from the opening 260-OP of the sensor inorganic layer 260 may be defined in the sensor organic layer 250. The sensor inorganic layer 260 and the sensor organic layer 250 may be patterned.

In an embodiment, an inorganic material may be deposited on the sensor organic layer 250 to form a preliminary sensor inorganic layer. A photoresist mask is formed on the preliminary sensor inorganic layer, and then the opening 260-OP of the sensor inorganic layer 260 and the cavity 250-CVT extending from the opening 260-OP may be patterned through a dry etching process. FIG. 6 illustrates that an edge of the opening 260-OP of the sensor inorganic layer 260 and an edge of the cavity 250-CVT of the sensor organic layer 250 are aligned. However, in some embodiments, the edges of the opening 260-OP and the cavity 250-CVT may not be aligned, or may not form a continuous, flat sidewall as in the embodiment of FIG. 6.

Thereafter, a preliminary color filter to be described later fills the opening 260-OP and the cavity 250-CVT, and then may be cured to form a plurality of color filters 320.

The anti-reflection layer ARL may be disposed on the input sensor IS. The anti-reflection layer ARL may include a light-blocking pattern 310, a plurality of color filter 320, and a planarization layer 330. However, the light-blocking pattern 310 may be omitted, and the light-blocking pattern 310 may serve as a substitute for the plurality of color filters 320 that may be overlapped.

A material constituting the light-blocking pattern 310 is not particularly limited as long as the material absorbs light. The light-blocking pattern 310 is a layer having a black color, and in an embodiment, the light-blocking pattern 310 may include a black coloring agent. The black coloring agent may include a black dye and a black pigment. The black coloring agent may include carbon black, metal such as chromium, or oxides thereof.

The light-blocking pattern 310 may prevent the external light from being reflected by the conductive patterns of the second sensor conductive layer 240 which is disposed below the light-blocking pattern 310. The light-blocking pattern 310 may also be omitted i parts of the display module DM. When the light-blocking pattern 310 is omitted, a region where the light-blocking pattern 310 is absent may have a higher transmittance than other regions.

An opening 310-OP may be defined in the light-blocking pattern 310. The opening 310-OP may overlap the first electrode AE of the light-emitting element LD on a plane. One of a plurality of color filters 320 may overlap the first electrode AE of the light-emitting element LD. One of the plurality of color filters 320 may cover the opening 310-OP. The plurality of color filters 320 may each be in contact with the light-blocking pattern 310.

The planarization layer 330 may cover the light-blocking pattern 310 and the plurality of color filters 320. The planarization layer 330 may include an organic material, and provide a flat surface on an upper surface of the planarization layer 330. The planarization layer 330 may include the same material as the sensor organic layer 250.

In an embodiment, the display module DM may not include a polarizing plate. Generally, when external light is incident on the polarizing plate disposed on the planarization layer 330, light reflected from an upper surface of the first electrode AE or a side surface of the light-emitting opening PDL-OP of the pixel defining layer PDL is restricted to propagating in a predefined direction. Hence, deterioration of visibility and display quality may be prevented. However, the light emitted from the light-emitting layer EL may be reduced. Therefore, in some cases, the display module DM may omit the polarizing plate to improve light emission efficiency and reduce power consumption used for displaying certain luminance.

Additionally, as described above, the pixel defining layer PDL may include a black coloring agent and form the light-blocking pattern 310 and a plurality of color filters 320 on the anti-reflection layer ARL while the polarizing plate is not formed on a front surface of the display panel DP according to an embodiment. Accordingly, even when external light enters the inside, the light reflected from the upper surface of the first electrode AE or the side surface of the light-emitting opening PDL-OP of the pixel defining layer PDL may be reduced, and color reproducibility and display quality may be improved.

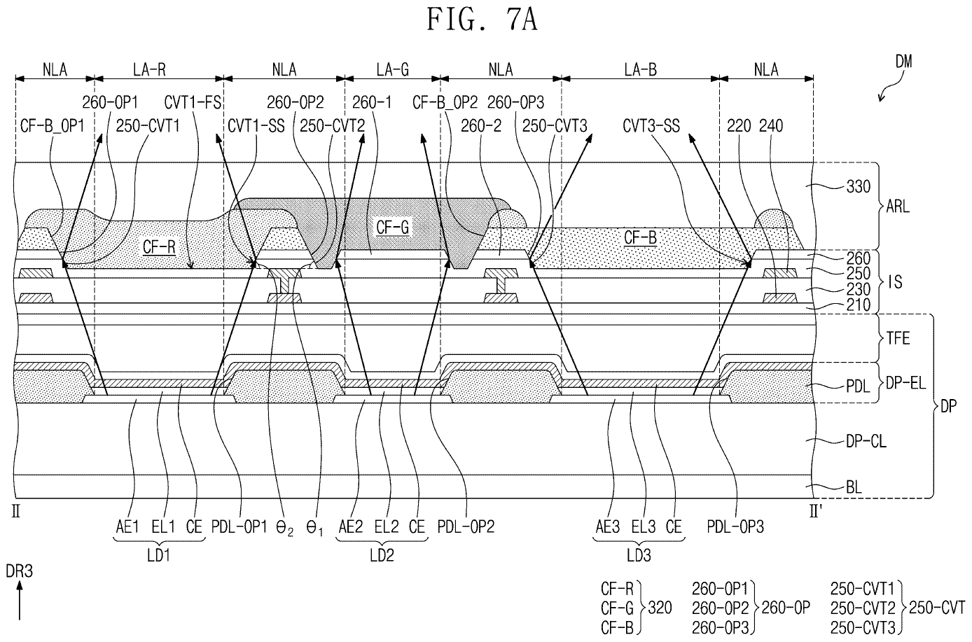

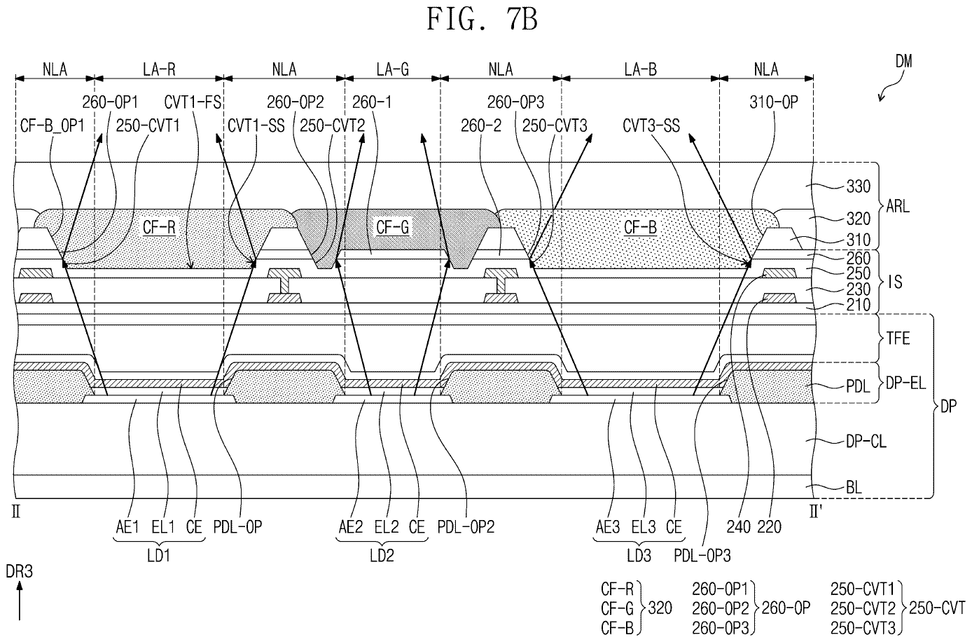

FIGS. 7A and 7B are respectively cross-sectional views of a display module DM according to an embodiment of the inventive concept.

In the interest of brevity, descriptions of FIGS. 7A and 7B pertaining to configurations that are the same as those described above with reference to FIGS. 4 and 6 will be omitted, and reference will be made to the descriptions of FIGS. 4 and 6.

FIGS. 7A and 7B illustrate that the display module DM includes a plurality of light-emitting regions LA-R, LA-G, LA-B and non-light-emitting regions NLA adjacent to the plurality of light-emitting regions LA-R, LA-G, LA-B. The non-light-emitting regions NLA may define the boundaries between the light-emitting regions LA-R, LA-G, and LA-B.

The light-emitting regions LA-R, LA-G, and LA-B may be disposed in a one-to-one correspondence to the pixels PX (see FIG. 5). Each of the pixels PX (see FIG. 5) includes a light-emitting element LD, and the light-emitting regions LA-R, LA-G, and LA-B may be regions in which light formed from the light-emitting element LD is emitted.

The light-emitting element LD may include a first light-emitting element LD1 emitting first-color light, a second light-emitting element LD2 emitting second-color light different from the first-color light, and a third light-emitting element LD3 emitting third-color light different from the first-color light and the second-color light. The first light-emitting element LD1, the second light-emitting element LD2 and the third light-emitting element LD3 are disposed to respectively correspond to the first light-emitting region LA-R, the second light-emitting region LA-G, and the third light-emitting region LA-B. In an embodiment, the first-color may be red, the second-color may be green, and the third-color may be blue.

The first light-emitting element LD1, the second light-emitting element LD2, and the third light-emitting element LD3 may respectively include first electrodes AE1, AE2, and AE3, light-emitting layers EL1, EL2, and EL3, and second electrodes CE.

The pixel defining layer PDL may define a first light-emitting opening PDL-OP1 that exposes the first electrode AE1 of the first light-emitting element LD1, a second light-emitting opening PDL-OP2 that exposes the first electrode AE1 of the second light-emitting element LD2, and a third light-emitting opening PDL-OP3 that exposes the first electrode AE1 of the third light-emitting element LD3.

A plurality of color filters 320 may include a first color filter CF-R disposed to overlap the first light-emitting element LD1, a second color filter CF-G disposed to overlap the second light-emitting element LD2, and a third color filter CF-B disposed to overlap the third light-emitting element LD3.

An opening 260-OP may be defined in the sensor inorganic layer 260, and the opening 260-OP may include a first opening 260-OP1, a second opening 260-OP2, and a third opening 260-OP3.

A cavity 250-CVT, which includes a first cavity 250-CVT1 extending from the first opening 260-OP1, a second cavity 250-CVT2 extending from the second opening 260-OP2, and a third cavity 250-CVT3 extending from the third opening 260-OP3, may be defined in the sensor organic layer 250.

In an embodiment, the refractive index of the sensor organic layer 250 may be smaller than the refractive indices of the respective first color filter CF-R and the third color filter CF-B, and may be larger than the refractive index of the second color filter CF-G. Due to the difference between the refractive index of the sensor organic layer 250 and the refractive indices of the plurality of color filters 320, the shapes of the first opening 260-OP1 and the third opening 260-OP3 may be different from the shape of the second opening 260-OP2.

According to an embodiment of the inventive concept, the opening 260-OP may include the first opening 260-OP1 overlapping the first light-emitting opening PDL-OP1. The area of the first opening 260-OP1 may be greater than the area of the first light-emitting region LA-R, but is not limited thereto.

The refractive index of the first color filter CF-R may be greater than the refractive index of the sensor organic layer 250, and the first opening 260-OP1, which overlaps the central region of the first electrode AE1, may be defined in the sensor inorganic layer 260.

When pressure is applied to the input sensor IS, the sensor inorganic layer 260 may disperse stress which is transferred from external pressure to the sensor organic layer 250 and the sensor conductive layer 240 disposed below the sensor inorganic layer 260. Additionally, since the opening 260-OP is defined in the sensor inorganic layer 260, cracks occurring when bending, folding, and rolling may be prevented, and stress applied to the entire sensor inorganic layer 260 may be reduced. Therefore, pressurized impact resistance and durability of a display device may be improved.

According to an embodiment of the inventive concept, the first cavity 250-CVT1 that is connected to the first opening 260-OP1 may be defined in the sensor organic layer 250. The first cavity 250-CVT1 defined in the sensor organic layer 250 may be referred to as an engraved pattern or a concave pattern. The sensor organic layer 250 may include a floor surface CVT1-FS, and a side surface CVT1-SS extending from the floor surface CVT1-FS so as to form an acute angle θ2, which defines the first cavity 250-CVT1. The side surface CVT1-SS of the first cavity 250-CVT1 may be formed as an inclined surface. Additionally, the central region of the first electrode AE1 may overlap the floor surface CVT1-FS of the first cavity 250-CVT1.

The first color filter CF-R may be disposed to overlap the first light-emitting element LD1 and be disposed within the first opening 260-OP1 and the first cavity 250-CVT1. The first color filter CF-R may transmit only a specific color among light formed from the first light-emitting element LD1, and thus color reproducibility may be further improved.

Among the light formed from the first light-emitting element LD1, the light passing through the side surface CVT1-SS of the first cavity 250-CVT1 may be refracted due to a difference in refractive indices between the sensor organic layer 250 and the first color filter CF-R. For example, when light having a wavelength of about 630 nm is emitted, the refractive index of the sensor organic layer 250 may be about 1.53, and the refractive index of the first color filter CF-R may be about 1.67. Since the refractive index of the sensor organic layer 250 is smaller than the refractive index of the first color filter CF-R, a refraction angle at the first color filter CF-R may decrease compared to an incident angle at the side surface CVT1-SS of the first cavity 250-CVT1. That is, since light passing through the side surface CVT1-SS of the first cavity 250-CVT1 may be refracted toward the first light-emitting region LA-R, the overall light emission efficiency may be increased, and the luminance of the display module DM may be improved.

According to an embodiment of the inventive concept, the opening 260-OP may further include a second opening 260-OP2, which does not overlap the second light-emitting opening PDL-OP2 and overlaps the pixel defining layer PDL. In an embodiment, the second opening 260-OP2 may surround the second light-emitting element LD2 in plan view.

The refractive index of the second color filter CF-G may be smaller than the refractive index of the sensor organic layer 250, and the second opening 260-OP2 may have a ring shape in plan view.

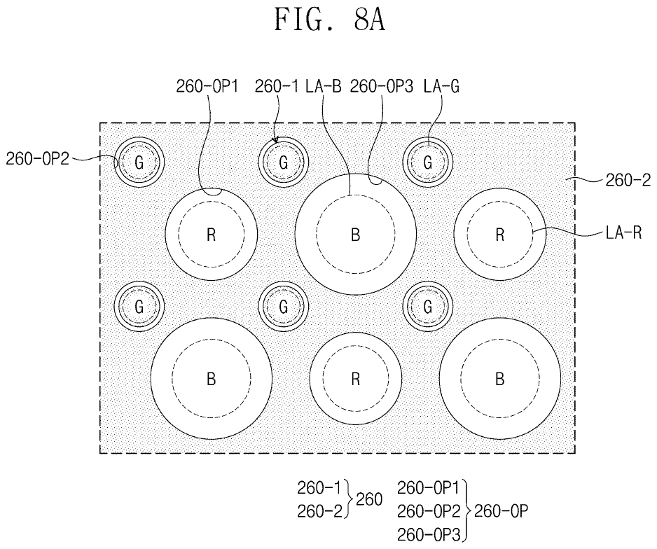

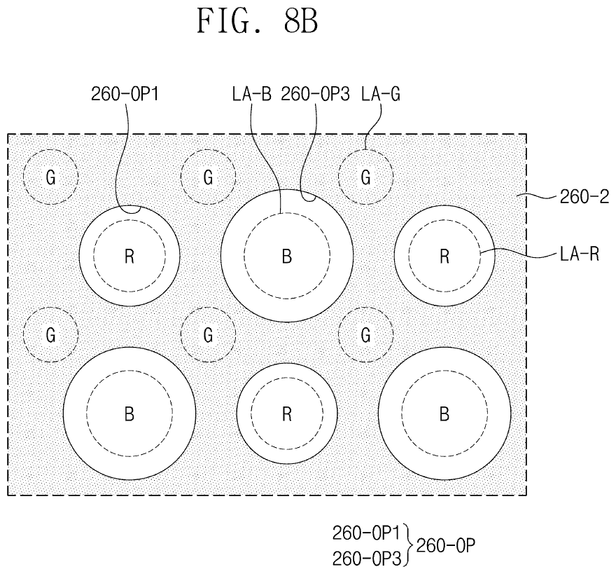

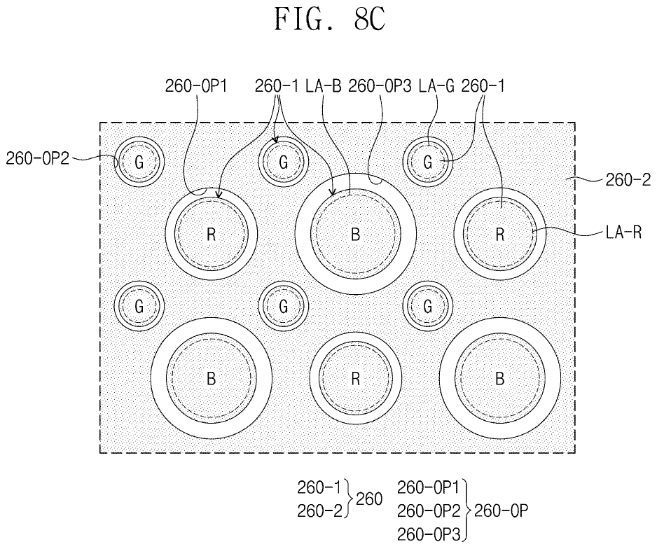

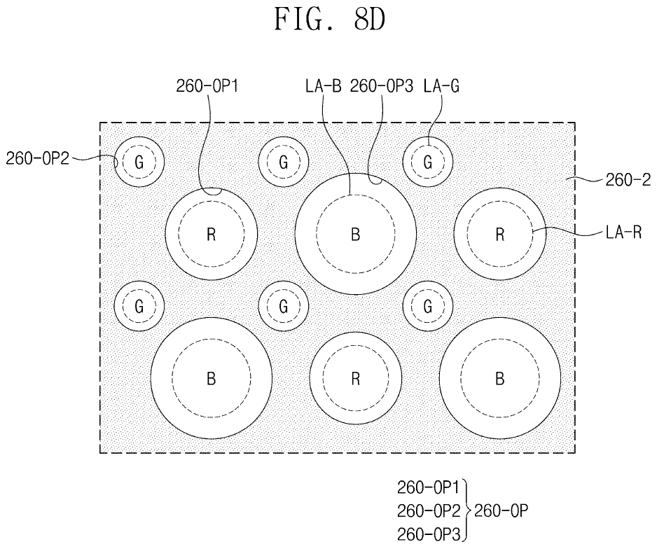

In an embodiment, the sensor inorganic layer 260 may include a first portion 260-1 disposed in the region surrounded by the second opening 260-OP2, and a second portion 260-2 disposed outside the second opening 260-OP2. The first portion 260-1 and the second portion 260-2 are spaced apart from the second opening 260-OP2 having a ring shape. The central region of the second light-emitting element LD2 may overlap the first portion 260-1. The details of the first portion 260-1 and the second portion 260-2 will be described later with reference to FIGS. 8A to 8D, which are plan views of the sensor inorganic layer 260.

The second cavity 250-CVT2 connected to the second opening 260-OP2 may be defined in the sensor organic layer 250. The second cavity 250-CVT2 defined in the sensor organic layer 250 may be an engraved pattern or a convex pattern. The sensor organic layer 250 may include a floor surface, and a side surface extending from the floor surface so as to form an acute angle θ1, which define the base of the second cavity 250-CVT2. In some embodiments, an inclination of the side surface of the second cavity 250-CVT2 is the same as the inclination of the side surface CVT1-SS of the first cavity 250-CVT1 (θ1=θ2), but an embodiment of the inventive concept is not necessarily limited thereto.

Among light formed from the second light-emitting element LD2, the light passing through the side surface of the second cavity 250-CVT2 may be refracted due to a difference in refractive indices between the sensor organic layer 250 and the second color filter CF-G. For example, when light having a wavelength of about 550 nm is emitted, the refractive index of the sensor organic layer 250 may be about 1.54, and the refractive index of the second color filter CF-G may be about 1.52. Since the refractive index of the sensor organic layer 250 is greater than the refractive index of the second color filter CF-G, a refraction angle at the second color filter CF-G may increase compared to an incident angle at the side surface of the second cavity 250-CVT2. Since the light passing through the side surface of the second cavity 250-CVT2 may be refracted toward the first light-emitting region LA-R, the overall light emission efficiency may be increased, and thus luminance of the display module DM may be improved.

In an embodiment, the opening 260-OP may include a third opening 260-OP3 overlapping the third light-emitting opening PDL-OP3. A third cavity 250-CVT3 connected to the third opening 260-OP3 may be defined in the sensor organic layer 250. Among light formed from the third light-emitting element LD3, the light passing through a side surface CVT3-SS of the third cavity 250-CVT3 may be refracted due to a difference in refractive indices between the sensor organic layer 250 and the third color filter CF-B. For example, when light having a wavelength of about 450 nm is emitted, the refractive index of the sensor organic layer 250 may be about 1.55, and the refractive index of the third color filter CF-B may be about 1.61. Since the refractive index of the sensor organic layer 250 is smaller than the refractive index of the third color filter CF-B, a refraction angle at the third color filter CF-B may decrease compared to an incident angle at the side surface of the third cavity 250-CVT3. Since the light passing through the side surface of the third cavity 250-CVT3 may be refracted toward the second light-emitting region LA-G, the overall light emission efficiency may be increased, and thus luminance of the display module DM may be improved.

Referring to FIG. 7A, the third color filter CF-B may be disposed to overlap the third light-emitting element LD3. Additionally, the third color filter CF-B may overlap the pixel defining layer PDL and the third light-emitting element LD3, and color openings CF-B_OP1 and CF-B_OP2 may be defined to respectively correspond to the first light-emitting element LD1 and the second light-emitting element LD2. A portion of the third color filter CF-B may overlap a portion of the first color filter CF-R, and a portion of the third color filter CF-B may overlap a portion of the second color filter CF-G. That is, the third color filter CF-B may be between the first color filter CF-R and the pixel defining layer PDL, and between the second color filter CF-G and the pixel defining layer PDL.

As the plurality of color filters 320 overlap the pixel define layer PDL, the light-blocking pattern 310 (see FIG. 6) may function as blocking unnecessary light, and thus color reproducibility may also be improved.

Referring to FIG. 7B, the anti-reflection layer ARL may include a light-blocking pattern 310 overlapping the pixel defining layer PDL between the openings 260-OP, and a plurality of color filters 320 on the light-blocking pattern 310. The plurality of color filters 320 may also be disposed inside of the cavity 250-CVT. A light-blocking pattern opening 310-OP connected to each of the openings 260-OP of the sensor inorganic layer 260 may be defined in the light-blocking pattern 310. Accordingly, since the light-blocking pattern 310 may control a path of light to block unnecessary light, light caused from unnecessary reflection may be absorbed or blocked, improving color reproducibility.

FIGS. 8A, 8B, 8C, and 8D are enlarged plan views of a portion of a sensor inorganic layer 260 according to an embodiment of the inventive concept.

Referring to FIGS. 7A and 8A together, although not illustrated in plan view, the plurality of color filters 320 overlapping the sensor inorganic layer 260 may be disposed outside the opening 260-OP of the sensor inorganic layer 260. Additionally, referring to FIGS. 7B and 8A together, although not illustrated in plan view, the plurality of color filters 320 and the light-blocking pattern 310 overlapping the sensor inorganic layer 260 may be further disposed outside the opening 260-OP of the sensor inorganic layer 260. The above-described content may be applied also to FIGS. 8B, 8C, and 8D, and the descriptions of configurations same as those described with reference to FIGS. 7A and 7B will be omitted to avoid redundancy. References may be made to the descriptions of FIGS. 7A and 7B for the parts that are the same.

In an embodiment, the refractive index of the first color filter CF-R and the refractive index of the third color filter CF-B are greater than the refractive index of the sensor organic layer 250, and the refractive index of the second color filter CF-G is smaller than the refractive index of the sensor organic layer 250. Accordingly, the first opening 260-OP1, which overlaps the first light-emitting region LA-R indicated by a dotted line, may be defined in the sensor inorganic layer 260, and the second opening 260-OP2 and the third opening 260-OP3 may be defined outside the second light-emitting region LA-G and the third light-emitting region LA-B which are indicated by broken lines.

In a plan view, a first opening 260-OP1 and a third opening 260-OP3 may each have a circular shape, and a second opening 260-OP2 may have a ring shape. However, the shape is not limited thereto. For example, the first opening 260-OP1 and the third opening 260-OP3 may each have a polygonal shape and the second opening 260-OP2 may have a polygonal shape that surrounds or frames a first portion 260-1.

In an embodiment, in plan view, the area of the first opening 260-OP1 may be greater than the area of the second opening 260-OP2 and smaller than the area of the third opening 260-OP3. However, the relative sizes of the opening 260-OP is not limited thereto and may vary according to light-emitting regions.

The sensor inorganic layer 260 may include a first portion 260-1 disposed inside the second opening 260-OP2, and a second portion 260-2 disposed outside the second opening 260-OP2. That is, the second portion 260-2 may extend continuously between openings 260-OP and may also include a portion disposed outside of the first opening 260-OP1. Since the second portion 260-2 of the sensor inorganic layer 260 has an integral shape, stress caused by external pressure may be dispersed, and impact resistance may be improved.

Referring to FIG. 8B, the configuration of FIG. 8B is the same as that of FIG. 8A except that the second opening 260-OP2 is not formed. The refractive index of the second color filter CF-G may be the same as refractive index of the sensor organic layer 250 in FIG. 8B. Accordingly, the second opening 260-OP2 (see FIG. 7A) corresponding to the second light-emitting element LD2 is not formed, and also the second cavity 250-CVT2 (see FIG. 7A) is not formed. Light may travel straight since the light formed from the second light-emitting element LD2 has a refraction angle and an incidence angle same as those of the sensor organic layer 250 and the second color filter CF-G.

Referring to FIG. 8C, the configuration of FIG. 8C is the same as that of FIG. 8A except that a first opening 260-OP1 and a third opening 260-OP3 each may be formed to have a ring shape like the second opening 260-OP2. Referring to FIG. 8C, since the refractive index of each of a first color filter CF-R and a third color filter CF-B is smaller than the refractive index of the sensor organic layer 250, a corresponding opening and cavity may each be formed to have a ring shape. Accordingly, the first portion 260-1 of the sensor inorganic layer 260 may be formed to overlap a first light-emitting region LA-R and a third light-emitting region LA-B.

Referring to FIG. 8D, second openings 260-OP2 corresponding to second light-emitting regions LA-G may also have a circular shape, similarly to a first opening 260-OP1 and the third opening 260-OP3. Since the refractive index of the second color filter CF-G in FIG. 8D may be greater than the refractive index of the sensor organic layer 250, the second opening 260-OP2 overlapping the second light-emitting region LA-G may be formed.

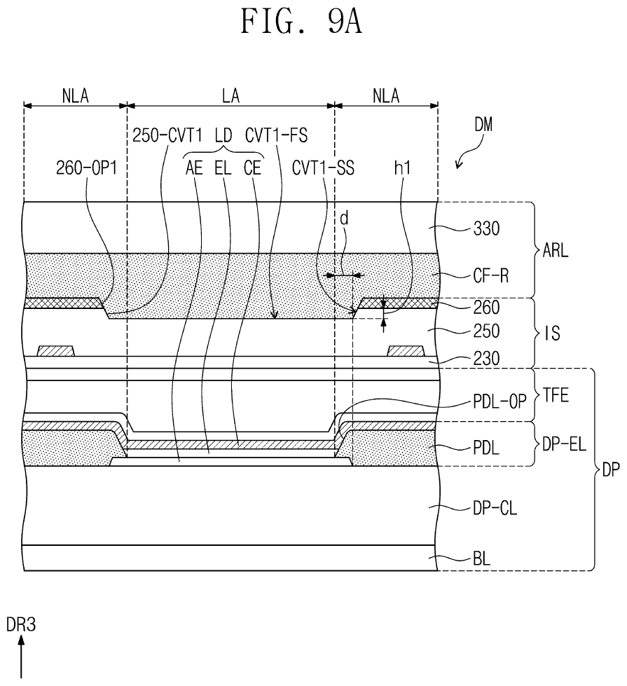

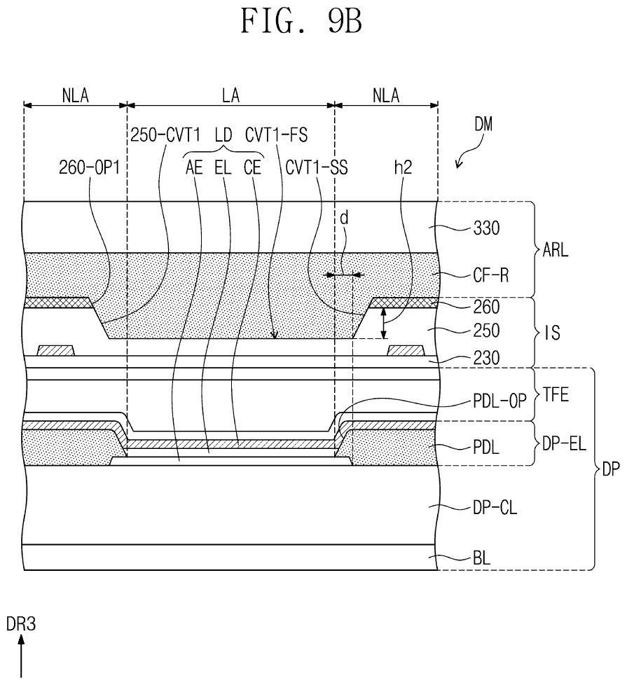

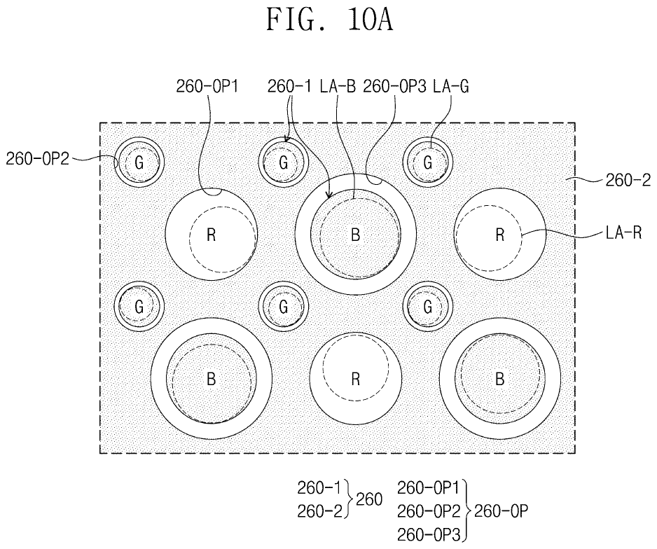

FIGS. 9A and 9B are enlarged cross-sectional views of a portion of a display module according to an embodiment of the inventive concept.

FIGS. 9A and 9B are cross-sectional views illustrating a sensor inorganic layer 260 and a sensor organic layer 250 in which a first opening 260-OP1 and a first cavity 250-CVT1 are defined.

A depth h1 of the first cavity 250-CVT1 in FIG. 9A may be measured. FIG. 9A depicts the depth h1 as being the distance between the upper surface of the sensor organic layer 250 and the floor surface CVT1-FS. This distance may be measured at the center of a floor surface CVT1-FS using an extrapolation of the upper surface of the sensor organic layer 250. The first cavity 250-CVT1 may have a depth h1 of about 0.5 μm to about 3.0 μm.

A depth h2 of the first cavity 250-CVT1 in FIG. 9B may be greater than the depth h1 of FIG. 9A. For example, as the depth of the first cavity 250-CVT1 is increased, a side surface CVT1-SS of the first cavity 250-CVT1 may be extended. Accordingly, since light passing through the side surface CVT1-SS may increase, light refracted toward the light-emitting region LA may increase. Thus, a light emission efficiency and luminance may be improved.

As illustrated in FIGS. 9A and 9B, a distance between the light-emitting region LA and an edge of the side surface CVT1-SS may be defined as a distance d. As used herein, the “edge of the side surface CVT1-SS” refers to where the side surface CVT1-SS of the first cavity 250-CVT1 meets the floor surface CVT1-FS. The distance d is also the distance between an edge of a light-emitting opening PDL-OP and the edge of the side surface CVT1-SS. As used herein, the “edge of a light-emitting opening PDL-OP” refers to where the sidewall of the light-emitting opening PDL-OP is closest to the circuit layer DP-CL. In plan view, the distance d between the edge of the light emitting region LA and the edge of the side surface CVT1-SS may be 0 to about 2.5 μm.

Since light from a light-emitting element LD may be incident on the side surface CVT1-SS of the first cavity 250-CVT1 at the distance d which is, on a plane, between the edge of the light-emitting opening PDL-OP and the edge of the side surface CVT1-SS of the first cavity 250-CVT1 and is within the above-described range, the light may be more easily refracted to the light-emitting region LA, improving light emission efficiency.

Table 1 below shows the improvement rate of a light emission efficiency according to the depths h1 or h2 of the first cavity 250-CVT1 and the distance d between the edge of the light-emitting opening PDL-OP and the first cavity 250-CVT1. An improvement rate % of the light emission efficiency of the display device including the display module DM of FIGS. 9A and 9B was measured on the basis of the display device including the display module in which the opening is not defined.

TABLE 1
Light emission Efficiency as a function of d and h

| Distance | Depth of First cavity (h1 or h2) [μm] | | | | | | | |
|---|---|---|---|---|---|---|---|---|
| d [μm] | 0.3 | 0.6 | 0.9 | 1.2 | 1.5 | 1.8 | 2.1 | 2.4 |
| 0.5 | 2.0% | 4.0% | 6.0% | 8.0% | 10.0% | 12.0% | 14.0% | 16.0% |
| 0 | 1.38% | 2.75% | 4.13% | 5.50% | 6.88% | 8.25% | 9.63% | 11.00% |

Referring to Table 1, it may be seen that as the depth of the first cavity 250-CVT1 increases, the light emission efficiency improves. However, when the depth becomes greater than a certain value, the conductive patterns protected by the sensor organic layer 250 may be exposed, which may result in a deterioration in durability. As the distance d between the edge of the light-emitting opening PDL-OP and the edge of the side surface CVT1-SS of the first cavity 250-CVT1 increases, light from the light-emitting element LD may be incident on the side surface CVT1-SS of the first cavity 250-CVT1, and the light emission efficiency is improved. However, when the distance between the edge of the light-emitting opening PDL-OP and the edge of the side surface CVT1-SS of the first cavity 250-CVT1 exceeds about 2.5 μm, the width of the first opening 260-OP1 (measured in plan view) might get too large and decrease the total area of the sensor inorganic layer 260. As a result, the impact resistance may go down.

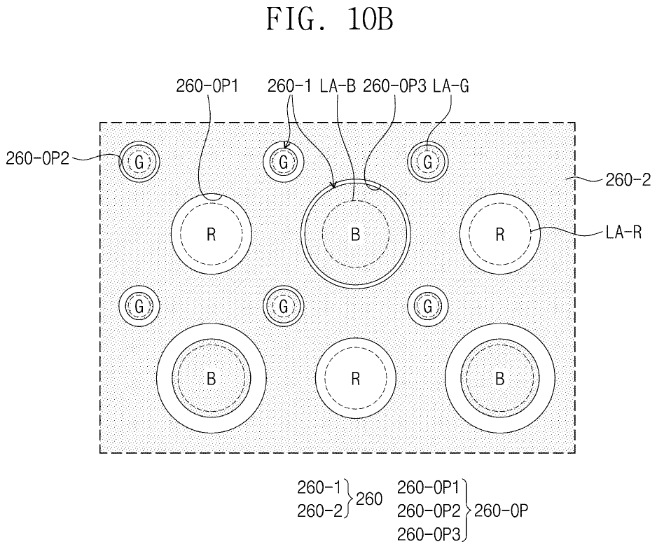

FIGS. 10A and 10B are respectively enlarged plan views of a portion of a sensor inorganic layer 260 according to an embodiment of the inventive concept.

FIG. 10A illustrates a shape in which an opening 260-OP of a sensor inorganic layer 260 is shifted with respect to the first light-emitting region LA-R, the second light-emitting region LA-G, and the third light-emitting region LA-B, and the cavity 250-CVT (see FIG. 7A). As described above in FIGS. 9A and 9B, the distance between the light-emitting region LA and the cavity 250-CVT (see FIG. 7A) may be varied, and the central region of the light-emitting region LA may also be shifted. Accordingly, dispersion may occur in the cavity 250-CVT (see FIG. 7A).

As illustrated in FIG. 10B, according to an area and a width of the opening 260-OP in some light-emitting regions among the first light-emitting region LA-R, the second light-emitting region LA-G, and the third light-emitting region LA-B, dispersion may occur also in the cavity 250-CVT (see FIG. 9A). For example, as the area and the width of the third opening 260-OP3 of FIG. 10B are decreased, a corresponding cavity may also have a decreased area and width. Accordingly, an area of a second portion 260-2 of the sensor inorganic layer 260 may be increased, and thus impact resistance may be improved.

According to an embodiment of the inventive concept, a display device and an electronic device include a sensor organic layer, and a sensor inorganic layer which is disposed on the sensor organic layer and in which an opening is defined, and thus it is possible to prevent progressive dark spots from being formed in the display device and the electronic device due to cracks occurring in an input sensor and propagation of the cracks. Therefore, a pressure-impact resistance and durability of the display device and the electronic device may be improved.

Also, according to an embodiment of the inventive concept, light from side surfaces of the display device and the electronic device is refracted, and may thus totally reflected as passing through a cavity of the sensor organic layer, thereby making it possible to improve a light emission efficiency of a front surface.

The above disclosure is made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims. Therefore, the technical scope of the inventive concept is not to be limited to the contents stated in the detailed description of the specification, but should be determined by the claims.

What is claimed is:

1. A display device comprising:
a display panel including a light-emitting element that includes at least one first electrode, at least one light-emitting layer disposed on the at least one first electrode, and a second electrode disposed on the light-emitting layer;
an input sensor disposed on the display panel; and
an anti-reflection layer disposed on the input sensor,
wherein the input sensor includes
a sensor conductive layer including a plurality of first conductive patterns,
a sensor organic layer configured to cover the plurality of first conductive patterns, and
a sensor inorganic layer disposed on the sensor organic layer and in contact with an upper surface of the sensor organic layer, and
an opening is defined in the sensor inorganic layer.

2. The display device of claim 1, wherein the display panel further comprises a pixel defining layer,
the light-emitting element comprises a first light-emitting element configured to generate first-color light,
a first light-emitting opening defined in the pixel defining layer and exposing one of the at least one first electrode of the first light-emitting element, and
the opening comprises a first opening overlapping the first light-emitting opening.

3. The display device of claim 2, wherein a first cavity connected to the first opening is defined in the sensor organic layer,
the sensor organic layer comprises a floor surface and a side surface extending from the floor surface to form an acute angle, the floor surface and the side surface defining the first cavity, and
a central region of the one of the at least one first electrode overlaps the floor surface of the first cavity.

4. The display device of claim 3, wherein the anti-reflection layer comprises a first color filter disposed in the first cavity to overlap the first light-emitting element, and
a refractive index of the first color filter is greater than a refractive index of the sensor organic layer.

5. The display device of claim 2, wherein the light-emitting element further comprises a second light-emitting element configured to generate second-color light different from the first-color light,
a second light-emitting opening is defined in the pixel defining layer and exposes another one of the at least one first electrode, and
the opening further comprises a second opening not overlapping the second light-emitting opening and overlapping the pixel defining layer.

6. The display device of claim 5, wherein the anti-reflection layer comprises a second color filter disposed to overlap the second light-emitting element,
a refractive index of the second color filter is smaller than a refractive index of the sensor organic layer, and
the second opening has a ring shape on a plane.

7. The display device of claim 6, wherein a second cavity connected to the second opening is further defined in the sensor organic layer, and
the second color filter is disposed in the second cavity.

8. The display device of claim 5, wherein on a plane, the sensor inorganic layer comprises a first portion surrounded by the second opening, and a second portion disposed outside the second opening.

9. The display device of claim 2, wherein the light-emitting element further comprises a third light-emitting element configured to generate third-color light different from the first-color light, and
the anti-reflection layer, in which a color opening overlapping the first light-emitting element is defined, comprises a third color filter overlapping the pixel define layer and the third light-emitting element.

10. The display device of claim 1, wherein the display panel further comprises a pixel defining layer,
the anti-reflection layer comprises a light-blocking pattern overlapping the pixel defining layer, and a color filter configured to cover the opening and the light-blocking pattern, and
the light-blocking pattern comprises a black coloring agent that absorbs light.

11. The display device of claim 1, wherein the display panel further comprises a pixel defining layer,
a light-emitting opening defined in the pixel defining layer and exposing the at least one first electrode,
a cavity connected to the opening is defined in the sensor organic layer,
the sensor organic layer comprises a floor surface and a side surface extending from the floor surface to form an acute angle and define the cavity, and
on a plane, a distance between an edge of the light-emitting opening and an edge of the side surface is about 2.5 μm or less.

12. The display device of claim 1, wherein a cavity connected to the opening is defined in the sensor organic layer,
the sensor organic layer comprises a floor surface and a side surface extending from the floor surface to form an acute angle and define the cavity, and
the cavity, measured from a center of the floor surface, has a depth of about 0.5 μm to about 3.0 μm.

13. A display device comprising:
a display panel including a light-emitting element; and
an input sensor disposed on the display panel,
wherein the display panel includes a pixel defining layer,
the light-emitting element includes a first electrode, a light-emitting layer disposed on the first electrode, and a second electrode disposed on the light-emitting layer,
a light-emitting opening is defined in the pixel defining layer and exposes the first electrode,
the input sensor includes a sensor conductive layer including a plurality of first conductive patterns, a sensor organic layer configured to cover the plurality of first conductive patterns, and an impact buffer layer disposed on the sensor organic layer and having a greater elastic modulus than the sensor organic layer,
an opening is defined in the impact buffer layer, and
a cavity is defined in the sensor organic layer, the cavity connected to the opening.

14. The display device of claim 13, wherein the impact buffer layer comprises a material having an elastic modulus of about 10 GPa to about 150 GPa.

15. The display device of claim 13, wherein an anti-reflection layer is disposed on the input sensor,
the anti-reflection layer comprises a color filter overlapping the light-emitting opening,
the light-emitting element comprises a first light-emitting element configured to emit first-color light, and a second light-emitting element configured to emit the second-color light different from the first-color light,
the color filter comprises a first color filter disposed to overlap the first light-emitting element, and a second color filter disposed to overlap the second light-emitting element,
a refractive index of the sensor organic layer is smaller than a refractive index of the first color filter and is greater than a refractive index of the second color filter, and
the opening comprises a first opening overlapping the light-emitting opening and a second opening overlapping the pixel define layer.

16. The display device of claim 15, wherein the cavity comprises a first cavity extending from the first opening, and a second cavity extending from the second opening.

17. The display device of claim 15, wherein on a plane, an area of the first opening is greater than an area of the second opening.

18. An electronic device comprising:
a display device;
an electronic module; and
a housing coupled to the display device,
wherein the display device includes
a display panel including a light-emitting element;
an input sensor disposed on the display panel; and
an anti-reflection layer disposed on the input sensor, and
the input sensor includes
a sensor conductive layer including a plurality of first conductive patterns
a sensor organic layer configured to cover the plurality of first conductive patterns, and
a sensor inorganic layer disposed on the sensor organic layer and in contact with an upper surface of the sensor organic layer,
an opening is defined in the sensor inorganic layer.

19. The electronic device of claim 18, wherein the display panel further comprises a pixel defining layer,
the light-emitting element comprises a first electrode, a light-emitting layer disposed on the first electrode, and a second electrode disposed on the light-emitting layer,
a light-emitting opening exposing to the first electrode is defined in the pixel define layer,
the opening comprises a first opening overlapping the light-emitting opening and a second opening overlapping the pixel define layer, and
a first cavity extending from the first opening and a second cavity extending from the second opening are defined in the sensor organic layer.

20. The electronic device of claim 18, wherein the display device does not comprise a polarizing plate.
